(19) United States
(12) Patent Application Publication
(10) Pub. No.: US 2023/0226824 A1
(43) Pub. Date: Jul. 20, 2023

(54) INKJET DEVICE

(71) Applicant: Samsung Display Co., LTD., Yongin-si (KR)

(72) Inventors: Jeong Won HAN, Seongnam-si (KR); Myung Soo HUH, Suwon-si (KR)

(21) Appl. No.: 18/078,059

(22) Filed: Dec. 8, 2022

(30) Foreign Application Priority Data
Jan. 18, 2022 (KR) 10-2022-0007481

(51) Int. Cl. B41J 2/185; B41J 2/165; B41M 5/00; H10K 71/00

(52) U.S. Cl. CPC B41J 2/185; B41J 2/1652; B41M 5/0047; H01L 51/56; B41J 2002/1853; H01L 2251/56

(57) ABSTRACT

An inkjet device includes: a stage in which a substrate is installed; a substrate mover which moves the substrate in a first direction; a processor which moves in the first direction together with the substrate mover; and an inkjet head disposed on the stage, where the processor includes a suction portion.

This application claims priority to Korean Patent Application No. 10-2022-0007481, filed on Jan. 18, 2022, and all the benefits accruing therefrom under 35 U.S.C. §119, the content of which in its entirety is herein incorporated by reference.

### BACKGROUND

### 1. Field

The disclosure relates to an inkjet device.

### 2. Description of the Related Art

Various types of a display device may include a liquid crystal display (LCD) device, a plasma display panel (PDP) device, an organic light emitting diode (OLED) device, a field emission display (FED) device, and an electrophoretic display device.

Recently, an inkjet method may be used to manufacture the display device.

A method for increasing efficiency of an inkjet process by supplying air between a substrate and a stage to reduce a frictional force between the stage and the substrate and allow the substrate to easily move on the stage when a manufacturing process is performed by using the inkjet method is proposed.

### SUMMARY

In a method for increasing efficiency of an inkjet process by supplying air between a substrate and a stage, ink particles that are discharged and remain for the inkjet process may be input into an air supplying hole for supplying air between the substrate and the stage. In this case, the air supply hole is clogged with the ink particles, such that a moving speed of the substrate may be changed, or a gap between the substrate and the stage may be changed, thereby changing a distance between an inkjet head and the substrate, which may cause product defects. The ink particles that are discharged and remain for the inkjet process may stick to other components of the inkjet device to cause pollution, and the pollution of the inkjet device may deteriorate efficiency of the manufacturing process and may induce deterioration of product quality.

Embodiments of the invention provide an inkjet device for preventing ink particles discharged and remaining for an inkjet process from sticking to the inkjet device.

An embodiment provides an inkjet device including: a stage in which a substrate is installed; a substrate mover which moves the substrate in a first direction; a processor which moves in the first direction together with the substrate mover; and an inkjet head disposed on the stage, where the processor includes a suction portion.

In an embodiment, the suction portion may be disposed between the stage and the inkjet head in a direction which is perpendicular to a surface of the stage.

In an embodiment, the processor may include a first processor and a second processor disposed opposite to each other with the substrate therebetween in the first direction.

In an embodiment, the suction portion may include a first suction portion disposed in the first processor and a second suction portion disposed in the second processor.

In an embodiment, each of the first suction portion and the second suction portion may extend in a second direction which is orthogonal to the first direction.

In an embodiment, each of a width of the first suction portion in the second direction and a width of the second suction portion in the second direction may be greater than a width of the substrate in the second direction.

In an embodiment, the first suction portion and the second suction portion may be disposed between the stage and the inkjet head in a third direction which is perpendicular to a surface of the stage.

In an embodiment, the first suction portion and the second suction portion may be disposed between the substrate and the inkjet head in the third direction.

In an embodiment, the stage may include a plurality of air holes.

In an embodiment, the substrate mover may further include a third suction portion.

In an embodiment, the third suction portion may extend in the first direction.

In an embodiment, the substrate mover may include a first substrate mover and a second substrate mover disposed opposite to each other with the substrate therebetween in a second direction which is orthogonal to the first direction.

In an embodiment, the first substrate mover may include a fourth suction portion, and the second substrate mover may include a fifth suction portion.

In an embodiment, each of the fourth suction portion and the fifth suction portion may extend in the first direction.

According to embodiments of the inkjet device, the ink particles discharged and remaining for the inkjet process may be prevented from sticking to the inkjet device such that the manufacturing efficiency is increased and the product quality is not deteriorated.

### BRIEF DESCRIPTION OF THE DRAWINGS

FIG. 1 shows a perspective view of an inkjet device according to an embodiment.

FIG. 2 shows a cross-sectional view of an inkjet device taken along line A-A of FIG. 1.

FIG. 3 shows a cross-sectional view of an inkjet device taken along line B-B of FIG. 1.

FIG. 4 shows a perspective view of an inkjet device according to an alternative embodiment.

FIG. 5 shows a perspective view of an inkjet device according to another alternative embodiment.

FIG. 6 shows a perspective view of an inkjet device according to another alternative embodiment.

FIG. 7 shows a flowchart of a manufacturing method using an inkjet device according to an embodiment.

FIG. 8 shows a cross-sectional view of a display device manufactured by a manufacturing method according to an embodiment.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art.

Parts that are irrelevant to the description will be omitted to clearly describe the embodiments, and Like reference numerals refer to like elements throughout.

The accompanying drawings are provided only in order to allow embodiments disclosed in the present specification to be easily understood and are not to be interpreted as limiting the spirit disclosed in the present specification, and it is to be understood that the embodiments includes all modifications, equivalents, and substitutions without departing from the scope and spirit of the embodiments.

The size and thickness of each configuration shown in the drawings are arbitrarily shown for better understanding and ease of description, but the embodiments are not limited thereto. The thickness of layers, films, panels, regions, etc., are enlarged for clarity. The thicknesses of some layers and areas are exaggerated for convenience of explanation.

It will be understood that when an element such as a layer, film, region, or substrate is referred to as being “on” another element, it can be directly on the other element or intervening elements may also be present. In contrast, when an element is referred to as being “directly on” another element, there are no intervening elements present. The word “on” or “above” means positioned on or below the object portion, and does not necessarily mean positioned on the upper side of the object portion based on a gravitational direction.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element’s relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

The phrase “in a plan view” means viewing an object portion from the top, and the phrase “in a cross-sectional view” means viewing a cross-section of which the object portion is vertically cut from the side.

When it is described that a part is “connected” to another part, the part may be “directly connected” to the other element, may be “connected” to the other part through a third part, or may be connected to the other part physically or electrically, and they may be referred to by different titles depending on positions or functions, but respective portions that are substantially integrated into one body may be connected to each other.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Various embodiments will hereinafter be described in detail with reference to the accompanying drawings.

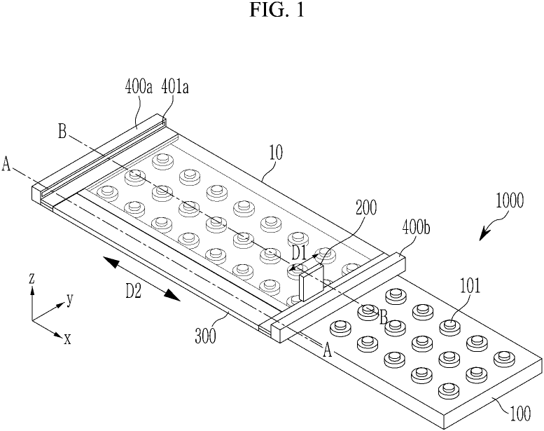

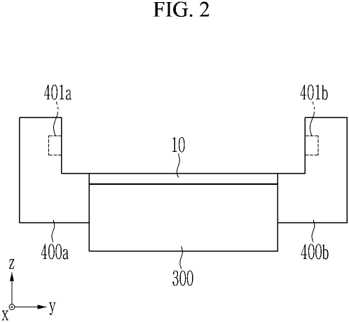

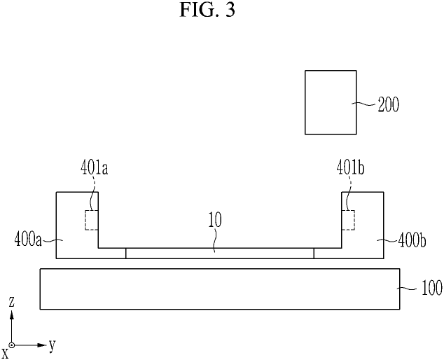

An inkjet device 1000 according to an embodiment will now be described with reference to FIG. 1 to FIG. 3. FIG. 1 shows a perspective view of an inkjet device according to an embodiment, FIG. 2 shows a cross-sectional view of an inkjet device taken along line A-A of FIG. 1, and FIG. 3 shows a cross-sectional view of an inkjet device taken along line B-B of FIG. 1.

Referring to FIG. 1 to FIG. 3, an embodiment of the inkjet device 1000 may include a stage 100 for supporting a substrate 10 on which processes are performed, an inkjet head 200 disposed on the stage 100, a substrate mover 300 attached to the substrate 10 for moving the substrate 10, and a first processor 400a and a second processor 400b disposed on the substrate mover 300 and at opposing sides of the substrate 10.

The stage 100 may include a plurality of air holes 101, and air supplied through the air holes 101 of the stage 100 is disposed between the stage 100 and the substrate 10 such the substrate 10 may move while floating from the stage 100.

The substrate 10 may move in a movement direction D2 that is parallel to a first direction (x-axis direction) on the stage 100. In an embodiment, a width of the stage 100 may be greater than twice the width of the substrate 10 in a direction parallel to the first direction (x-axis direction). In such an embodiment where the width of the stage 100 is greater than twice the width of the substrate 10 in the movement direction D2 in which the substrate 10 moves as described above, the substrate 10 may be stably supported while the substrate 10 moves and the process is performed.

The inkjet head 200 of the inkjet device 1000 may travel back and forth in a driving direction D1 in parallel to a second direction (y-axis direction) that is orthogonal to the first direction (x-axis direction).

The substrate 10 may move in the movement direction D2 that is parallel to the first direction (x-axis direction) on the stage 100, and the inkjet head 200 of the inkjet device 1000 may move back and forth in the driving direction D1 that is parallel to the second direction (y-axis direction) that is orthogonal to the first direction (x-axis direction) and may drip inkjet ink so that the process may be progressed.

In an embodiment, droplets of the inkjet device 1000 may be high-molecular low-molecular organic materials corresponding to the emission layer of the organic light emitting device, and may be red, green, and blue ink in which pigment particles are mixed with liquid crystal, an aligning agent, and a solvent.

The first processor 400a and the second processor 400b may be disposed below the inkjet head 200 and above the stage 100 in a third direction (z-axis direction) that is perpendicular to a surface of the substrate 10.

The first processor 400a and the second processor 400b may be disposed opposite to each other with the substrate 10 therebetween in the first direction (x-axis direction) that is parallel to the movement direction D2 of the substrate 10, and may be connected to the substrate mover 300 so when the substrate 10 moves in the movement direction D2, the first processor 400a and the second processor 400b may move in the movement direction D2.

In an embodiment, as shown in FIG. 2, the first processor 400a includes a first suction portion 401a and the second processor 400b includes a second suction portion 401b. The first suction portion 401a of the first processor 400a and the second suction portion 401b of the second processor 400b may extend in a direction that is parallel to the second direction (y-axis direction) and may have a width (i.e., a length in the driving direction D1) that is equal to or greater than the width of the substrate 10.

In an embodiment, while the substrate 10 moves in the movement direction D2 and the inkjet head 200 moves back and forth in the driving direction D1 and drips ink to progress the inkjet process, the first processor 400a and the second processor 400b move in the movement direction D2, and the first suction portion 401a of the first processor 400a and the second suction portion 401b of the second processor 400b may inhale residual ink mist sprayed into the air from among the ink discharged from the inkjet head 200 and dripped on the substrate 10. Accordingly, in such an embodiment, the ink mist is effectively prevented from being polluted due to being absorbed to other components of the inkjet device 1000 and the inkjet device 1000.

Referring to FIG. 3, in an embodiment, the first suction portion 401a of the first processor 400a and the second suction portion 401b of the second processor 400b may be disposed between the inkjet head 200 and the stage 100 in the third direction (z-axis direction) that is perpendicular to the surface of the substrate 10 so the residual ink mist sprayed into the air from among the ink discharged from the inkjet head 200 and dripped on the substrate 10 may, before reaching the stage 100, be inhaled by the first suction portion 401a of the first processor 400a and the second suction portion 401b of the second processor 400b. Accordingly, in such an embodiment, the residual ink mist sprayed into the air may be effectively prevented from being input into the air holes 101 of the stage 100.

In an embodiment, as described above, the substrate 10 may move while floating from the stage 100 by the air supplied from the air holes 101 of the stage 100. When a constant amount of air is supplied from the air holes 101 of the stage 100, a gap between the stage 100 and the substrate 10 in the third direction (z-axis direction) may be maintained, and thus, a gap between the inkjet head 200 and the surface of the substrate 10 in the third direction (z-axis direction) may be maintained while the substrate 10 moves toward the inkjet head 200 in a direction that is parallel to the first direction (x-axis direction) and the process is performed. When a non-uniform amount of air is supplied from the air holes 101 of the stage 100 depending on the position, the gap between the inkjet head 200 and the surface of the substrate 10 in the third direction (z-axis direction) may not be constant, and when the gap between the substrate 10 and the inkjet head 200 is non-uniform, non-uniformity may be generated in the manufacturing process.

In embodiments of the inkjet device 1000 according to the invention, the first suction portion 401a of the first processor 400a and the second suction portion 401b of the second processor 400b may be disposed between the inkjet head 200 and the stage 100 in the third direction (z-axis direction) that is perpendicular to the surface of the substrate 10, and the residual ink mist sprayed into the air from among the ink discharged from the inkjet head 200 may, before reaching the stage 100, be inhaled by the first suction portion 401a of the first processor 400a and the second suction portion 401b of the second processor 400b. In such embodiments, the residual ink mist sprayed into the air may be effectively prevented from being input into the air holes 101 of the stage 100. Therefore, the amount of the air supplied from the air holes 101 of the stage 100 may be maintained, and the gap between the substrate 10 and the inkjet head 200 may be maintained.

If the suction portion for removing the residual ink is disposed near the inkjet head, some of the droplets dripped from the inkjet head are undesirably inhaled to reduce processing efficiency, and if the suction portion for removing the residual ink is disposed to be lower than the air hole of the stage, the residual ink may be partly inhaled into the air hole of the stage before being inhaled by the suction portion, and the residual ink may stick to the substrate before being inhaled by the suction portion.

In embodiments of the inkjet device 1000 according to the invention, the residual ink mist sprayed into the air in the inkjet process may, before reaching the stage 100, be inhaled by the first suction portion 401a of the first processor 400a and the second suction portion 401b of the second processor 400b, thereby increasing process efficiency, and preventing the ink mist from being input to the substrate 10 and the air holes 101 of the stage 100.

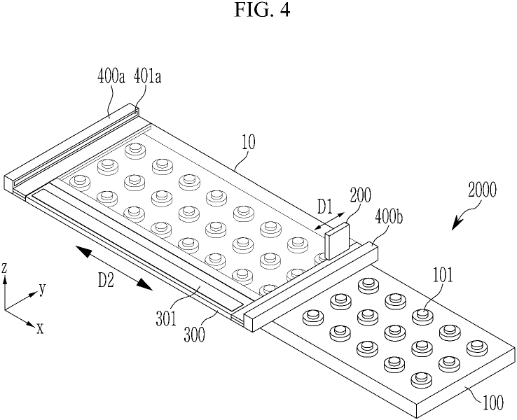

An inkjet device 2000 according to an alternative embodiment will now be described with reference to FIG. 4 together with FIG. 1 to FIG. 3. FIG. 4 shows a perspective view of an inkjet device according to an alternative embodiment.

An embodiment of the inkjet device 2000 shown in FIG. 4 is substantially the same as the embodiment of the inkjet device 1000 described above with reference to FIG. 1 to FIG. 3. Accordingly, any repetitive detailed description of the same or like constituent elements in FIG. 4 as those described above with reference to FIG. 1 to FIG. 3 will be omitted or simplified.

Referring to FIG. 4, an embodiment of the inkjet device 2000 may include a stage 100 for supporting the substrate 10 on which processes are performed, an inkjet head 200 disposed on the stage 100, a substrate mover 300 attached to the substrate 10 for moving the substrate 10, and a first processor 400a and a second processor 400b disposed on the substrate mover 300 and at opposite sides of the substrate 10.

The stage 100 may include a plurality of air holes 101. The first processor 400a may include a first suction portion 401a, the second processor 400b may include a second suction portion 401b, and the substrate mover 300 may include a third suction portion 301. The third suction portion 301 of the substrate mover 300 may extend in the first direction (x-axis direction), and may have substantially the same width as the substrate 10 in the first direction (x-axis direction).

While the substrate 10 moves in the movement direction D2 through the substrate mover 300 and the inkjet head 200 moves back and forth in the driving direction D1 and drips ink to progress the inkjet process, the first processor 400a and the second processor 400b may move in the movement direction D2, the first suction portion 401a of the first processor 400a, the second suction portion 401b of the second processor 400b, and the third suction portion 301 of the substrate mover 300 may inhale the residual ink mist sprayed into the air from among the ink discharged from the inkjet head 200 and dripped on the substrate 10. Accordingly, in such an embodiment, the ink mist is effectively prevented from being polluted due to being absorbed to other components of the inkjet device 1000 and the inkjet device 1000.

In embodiments of the inkjet device 2000 according to the invention, the first suction portion 401a of the first processor 400a and the second suction portion 401b of the second processor 400b may be disposed between the inkjet head 200 and the stage 100 in the third direction (z-axis direction) that is perpendicular to the surface of the substrate 10, and the residual ink mist sprayed into the air from among the ink discharged from the inkjet head 200 may, before reaching the stage 100, be inhaled by the first suction portion 401a of the first processor 400a and the second suction portion 401b of the second processor 400b. The residual ink mist sprayed into the air from among the ink discharged from the inkjet head 200 may be additionally inhaled in a direction that is parallel to the movement direction D2 of the substrate 10 through the third suction portion 301 of the substrate mover 300. Accordingly, in such embodiments, the residual ink mist sprayed into the air may be effectively prevented from being input into the substrate 10 and the air holes 101 of the stage 100.

Other features of the embodiments of the inkjet device 1000 described above with reference to FIG. 1 to FIG. 3 are applicable to the embodiment of the inkjet device 2000 shown in FIG. 4.

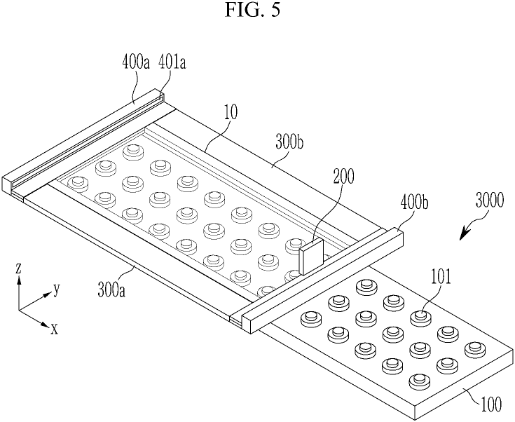

An inkjet device 3000 according to another alternative embodiment will now be described with reference to FIG. 5 together with FIG. 1 to FIG. 3. FIG. 5 shows a perspective view of an inkjet device according to another alternative embodiment.

An embodiment of the inkjet device 3000 shown in FIG. 5 is substantially the same as the embodiment of the inkjet device 1000 described above with reference to FIG. 1 to FIG. 3. Accordingly, any repetitive detailed description of the same or like constituent elements in FIG. 5 as those described above with reference to FIG. 1 to FIG. 3 will be omitted or simplified.

Referring to FIG. 5, an embodiment of the inkjet device 3000 may include a stage 100 for supporting the substrate 10 on which processes are performed, an inkjet head 200 disposed on the stage 100, substrate movers 300a and 300b attached to the substrate 10 for moving the substrate 10, and a first processor 400a and a second processor 400b disposed on the substrate movers 300a and 300b at opposite sides of the substrate 10 in the first direction (x-axis direction) that is parallel to the movement direction D2 of the substrate 10.

The stage 100 may have a plurality of air holes 101. The first processor 400a may include a first suction portion 401a, the second processor 400b may include a second suction portion 401b. In such an embodiment, the substrate mover 300 may further include a third suction portion 301 shown in FIG. 4.

The substrate movers 300a and 300b may include a first substrate mover 300a and a second substrate mover 300b disposed opposite to each other with the substrate 10 therebetween in the second direction (y-axis direction) that is orthogonal to the movement direction DR2 of the substrate 10. As the first substrate mover 300a and the second substrate mover 300b disposed on the opposite sides of the substrate 10 are included, the substrate 10 may be further easily moved.

While the substrate 10 moves in the movement direction D2 through the substrate mover 300 and the inkjet head 200 moves back and forth in the driving direction D1 and drips ink to progress the inkjet process, the first processor 400a and the second processor 400b may move in the movement direction D2, and the first suction portion 401a of the first processor 400a, the second suction portion 401b of the second processor 400b, and the third suction portion 301 of the substrate mover 300 may inhale the residual ink mist sprayed into the airfrom among the ink discharged from the inkjet head 200 and dripped on the substrate 10. Accordingly, in such an embodiment, ink mist is effectively prevented from being polluted due to being absorbed to other components of the inkjet device 1000 and the inkjet device 1000.

In embodiments of the inkjet device 3000 according to the invention, the first suction portion 401a of the first processor 400a and the second suction portion 401b of the second processor 400b may be disposed between the inkjet head 200 and the stage 100 in the third direction (z-axis direction) that is perpendicular to the surface of the substrate 10, and the residual ink mist sprayed into the air from among the ink discharged from the inkjet head 200 may, before reaching the stage 100, be inhaled by the first suction portion 401a of the first processor 400a and the second suction portion 401b of the second processor 400b. Accordingly, in such embodiments, the residual ink mist sprayed into the air may be effectively prevented from being input into the substrate 10 and the air holes 101 of the stage 100.

Other features of the embodiments of the inkjet device 1000 described above with reference to FIG. 1 to FIG. 3 are applicable to the embodiment of the inkjet device 3000 shown in FIG. 5.

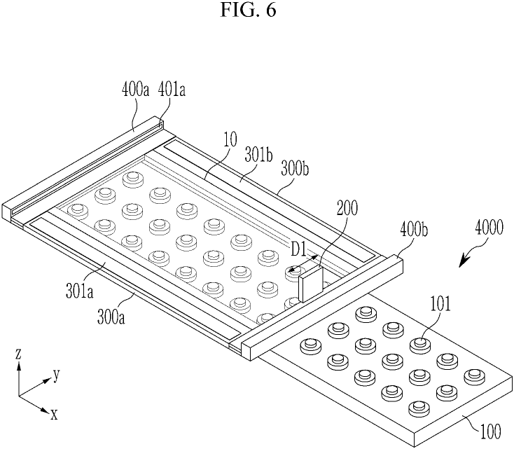

An inkjet device 4000 according to another alternative embodiment will now be described with reference to FIG. 6 together with FIG. 1 to FIG. 3. FIG. 6 shows a perspective view of an inkjet device according to another alternative embodiment.

An embodiment of the inkjet device 4000 shown in FIG. 6 is substantially the same as the embodiment of the inkjet device 1000 described above with reference to FIG. 1 to FIG. 3. Accordingly, any repetitive detailed description of the same or like constituent elements in FIG. 6 as those described above with reference to FIG. 1 to FIG. 3 will be omitted or simplified.

Referring to FIG. 6, an embodiment of the inkjet device 4000 may include a stage 100 for supporting the substrate 10 on which processes are performed, an inkjet head 200 disposed on the stage 100, substrate movers 300a and 300b attached to the substrate 10 for moving the substrate 10, and a first processor 400a and a second processor 400b disposed on the substrate mover 300 and at the opposite sides of the substrate 10.

The stage 100 may have a plurality of air holes 101. The first processor 400a may include a first suction portion 401a, and the second processor 400b may include a second suction portion 401b.

The substrate movers 300a and 300b may include a first substrate mover 300a and a second substrate mover 300b disposed opposite to each other with the substrate 10 therebetween in the second direction (y-axis direction) that is orthogonal to the movement direction DR2 of the substrate 10. As the first substrate mover 300a and the second substrate mover 300b disposed on the opposite sides of the substrate 10 are included, the substrate 10 may be further easily moved.

In an embodiment, the first substrate mover 300a and the second substrate mover 300b may include a fourth suction portion 301a and a fifth suction portion 301b extending in the first direction (x-axis direction) in parallel to the movement direction D2. The fourth suction portion 301a and the fifth suction portion 301b may have substantially the same width as the substrate 10 in the first direction (x-axis direction).

While the substrate 10 moves in the movement direction D2 through the substrate movers 300a and 300b, and the inkjet head 200 moves back and forth in the driving direction D1 to drip the ink and thereby perform the inkjet process, the first processor 400a and the second processor 400b may move in the movement direction D2, and the first suction portion 401a of the first processor 400a, the second suction portion 401b of the second processor 400b, and the third suction portion 301 of the substrate mover 300 may inhale the residual ink mist sprayed into the air from among the ink discharged from the inkjet head 200 and dripped on the substrate 10. The residual ink mist may be additionally inhaled through the fourth suction portion 301a and the fifth suction portion 301b of the first substrate mover 300a and the second substrate mover 300b. The residual ink mist may be inhaled along the edge of the substrate 10, thereby increasing the inhale efficiency of the residual ink mist. Accordingly, in such an embodiment, the residual ink mist is effectively prevented from being polluted due to being absorbed to other components of the inkjet device 1000 and the inkjet device 1000.

According to embodiments of the inkjet device 3000 according to the invention, the first suction portion 401a of the first processor 400a and the second suction portion 401b of the second processor 400b may be disposed between the inkjet head 200 and the stage 100 in the third direction (z-axis direction) that is perpendicular to the surface of the substrate 10, and the residual ink mist sprayed into the air from among the ink discharged from the inkjet head 200 may, before reaching the stage 100, be inhaled by the first suction portion 401a of the first processor 400a and the second suction portion 401b of the second processor 400b. Accordingly, in such embodiments, the residual ink mist sprayed into the air may be effectively prevented from being input into the substrate 10 and the air holes 101 of the stage 100.

Other features of the embodiments of the inkjet device 1000 described above with reference to FIG. 1 to FIG. 3 are applicable to the embodiment of the inkjet device 4000 shown in FIG. 6.

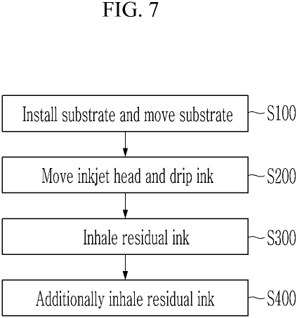

A manufacturing method using an inkjet device according to an embodiment will now be described with reference to FIG. 7 together with FIG. 1 to FIG. 6. FIG. 7 shows a flowchart of a manufacturing method using an inkjet device according to an embodiment.

Referring to FIG. 7 together with FIG. 1 to FIG. 6, an embodiment of the manufacturing method using an inkjet device may include: mounting a substrate 10 on which processes will be performed on a stage 100, and moving the substrate 10 in the movement direction D2 through the substrate mover 300 (S100); and moving the inkjet head 200 back and forth in the driving direction D1 and dripping ink from the inkjet head 200 (S200).

In such an embodiment, the manufacturing method may further include suctioning a residual ink mist by using a first suction portion 401a of a first processor 400a and a second suction portion 401b of a second processor 400b (S300).

The first suction portion 401a of the first processor 400a and the second suction portion 401b of the second processor 400b may move in the movement direction D2 together with the substrate mover 300 and the substrate 10.

The first suction portion 401a of the first processor 400a and the second suction portion 401b of the second processor 400b may be disposed between the inkjet head 200 and the stage 100 in the third direction (z-axis direction) that is perpendicular to the surface of the substrate 10, and the residual ink mist sprayed into the air from among the ink discharged from the inkjet head 200 may, before reaching the stage 100, be inhaled by the first suction portion 401a of the first processor 400a and the second suction portion 401b of the second processor 400b.

The suctioning of a residual ink mist (S300) may include additionally suctioning the residual ink mist through a third suction portion 301 formed on the substrate mover 300 or the fourth suction portion 301a and the fifth suction portion 301b formed on the substrate movers 300a and 300b (S400).

As described above, an embodiment of the manufacturing method according to the invention may include additionally suctioning the residual ink mist through a third suction portion 301 formed on the substrate mover 300 or the fourth suction portion 301a and the fifth suction portion 301b formed on the substrate movers 300a and 300b. Accordingly, the residual ink mist may be inhaled along the edge of the substrate 10, and the efficiency of suctioning the residual ink mist may be increased.

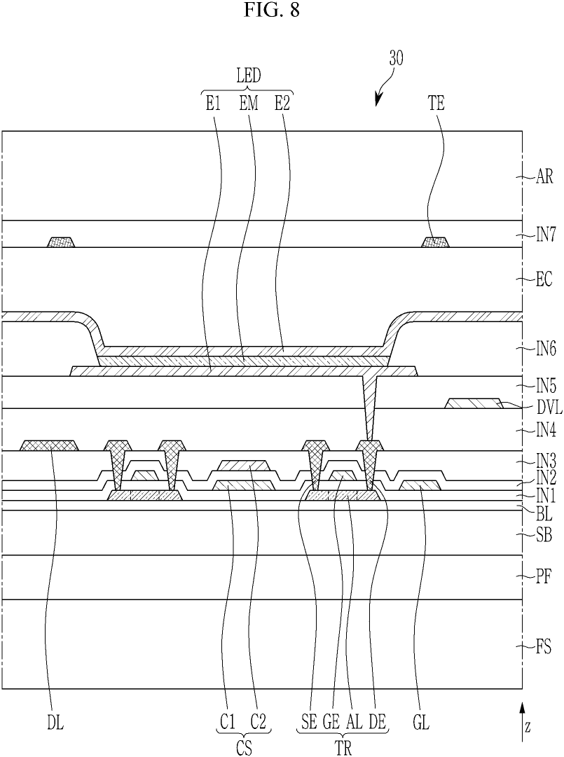

An display device formed by a manufacturing method using an inkjet device according to an embodiment will now be described with reference to FIG. 8. FIG. 8 shows a cross-sectional view of a pixel of a display device made by a manufacturing method according to an embodiment.

Referring to FIG. 8, the display device 30 formed by the manufacturing method using an inkjet device according to an embodiment includes a substrate SB, a transistor TR disposed on the substrate SB, and a light emitting diode LED connected to the transistor TR. The light emitting diode LED may correspond to the pixel.

The substrate SB may be a flexible substrate including or made of a polymer such as a polyimide, a polyamide, or a polyethylene terephthalate. The substrate SB may include a barrier layer for preventing permeation of moisture or oxygen. For example, the substrate SB may include at least one polymer layer and at least one barrier layer, and the polymer layer and the barrier layer may be alternately stacked one on another.

A buffer layer BL may be disposed on the substrate SB. The buffer layer BL may include an inorganic insulating material such as a silicon oxide or a silicon nitride.

A semiconductor layer AL of the transistor TR may be disposed on the buffer layer BL, and an insulating layer IN1 may be disposed on the semiconductor layer AL. The semiconductor layer AL may include a source region, a drain region, and a channel region therebetween. The semiconductor layer AL may include a semiconductor material such as polysilicon, an oxide semiconductor, or amorphous silicon.

A first conductor including a gate electrode GE of the transistor TR, a gate line GL, and a first electrode C1 of the capacitor CS may be disposed on the insulating layer IN1.

An insulating layer IN2 may be disposed on the first conductor. A second conductor including a second electrode C2 of the capacitor CS may be disposed on the insulating layer IN2. The first conductor and/or the second conductor may include a metal such as molybdenum (Mo), copper (Cu), aluminum (Al), silver (Ag), chromium (Cr), tantalum (Ta), or titanium (Ti).

An insulating layer IN3 may be disposed on the insulating layer IN2 and the second conductor. The insulating layers IN1, IN2, and IN3 may include an inorganic insulating material.

A third conductor including a source electrode SE and a drain electrode DE of the transistor TR, and a data line DL may be disposed on the insulating layer IN3. The source electrode SE and the drain electrode DE may be respectively connected to the source region and the drain region of the semiconductor layer AL through openings of the insulating layers IN1, IN2, and IN3.

An insulating layer IN4 may be disposed on the third conductor. A fourth conductor including a driving voltage line DVL may be disposed on the insulating layer IN4. The third conductor and the fourth conductor may include a metal such as aluminum (Al), copper (Cu), silver (Ag), molybdenum (Mo), chromium (Cr), gold (Au), platinum (Pt), palladium (Pd), tantalum (Ta), tungsten (W), titanium (Ti), or nickel (Ni), or a metal alloy thereof.

An insulating layer IN5 may be disposed on the fourth conductor. The insulating layers IN4 and IN5 may include an organic insulating material.

A first electrode E1 of the light emitting diode LED may be disposed on the insulating layer IN5. The first electrode E1 may be referred to as a pixel electrode. The first electrode E1 may be connected to the drain electrode DE through openings of the insulating layers IN4 and IN5 and may receive a data signal for controlling luminance of the light emitting diode LED. The transistor TR to which the first electrode E1 is connected may be a driving transistor or a transistor electrically connected to the driving transistor.

An insulating layer IN6 may be disposed on the insulating layer IN5. The insulating layer IN6 may be referred to as a pixel defining layer, and may have an opening overlapping the first electrode E1. An emission member EM including an emission layer may be disposed on the first electrode E1 in the opening of the insulating layer IN6, and the second electrode E2 may be disposed on the emission member EM. The second electrode E2 may be referred to as a common electrode.

The first electrode E1, the emission member EM, and the second electrode E2 may configure a light emitting diode LED that may be an organic light emitting diode. The first electrode E1 and the second electrode may be an anode and a cathode of the light emitting diode LED, respectively.

An encapsulation layer EC may be disposed on the second electrode E2. The encapsulation layer EC may encapsulate the light emitting diode LED to prevent moisture or oxygen from permeating from the outside. The encapsulation layer EC may be a thin film encapsulation layer including at least one inorganic material layer and at least one organic material layer.

A touch sensor layer including a touch electrode TE may be disposed on the encapsulation layer EC. The touch electrode TE may have a mesh shape with an opening overlapping the light emitting diode LED. A buffer layer (not shown) may be disposed between the encapsulation layer EC and the touch sensor layer. An insulating layer IN7 for covering the touch electrode TE may be disposed on the touch sensor layer.

An antireflection layer AR for reducing reflection of external light may be disposed on the insulating layer IN7. The antireflection layer AR may include a polarization layer. The antireflection layer AR may be attached by an adhesive or may be formed on the insulating layer IN7. In an embodiment, the antireflection layer AR may be omitted, and the encapsulation layer EC, the touch sensor layer, and/or the insulating layer IN7 may be formed to be a refractive index matching structure and may thus obtain an antireflection effect. The layers disposed between the substrate SB and the antireflection layer AR may correspond to the above-described pixel layer PL.

A protection film PF for protecting the display device may be disposed below the substrate SB. The protection film PF may include or be made of a polymer such as a polyethylene terephthalate, a polyethylene naphthalate, or a polyimide. In an embodiment, the protection film PF may not be disposed in the bending region BR to reduce a bending stress of a bending region BR. A bending protection layer (a stress easing layer) may be disposed in the bending region BR so that wires disposed in the bending region BR may not be disconnected or damaged.

A functional sheet FS including at least one selected from a cushion layer, a heat radiation sheet, a light blocking sheet, a watertight tape, and an electromagnetic blocking film may be disposed below the protection film PF. The functional sheet FS may not be disposed in the bending region BR and on the pad portion PP.

The invention should not be construed as being limited to the embodiments set forth herein. Rather, these embodiments are provided so that this disclosure will be thorough and complete and will fully convey While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. An inkjet device comprising:
a stage in which a substrate is installed;
a substrate mover which moves the substrate in a first direction;
a processor which moves in the first direction together with the substrate mover; and
an inkjet head disposed on the stage,
wherein the processor includes a suction portion.

2. The inkjet device of claim 1, wherein
the suction portion is disposed between the stage and the inkjet head in a direction perpendicular to a surface of the stage.

3. The inkjet device of claim 1, wherein
the processor includes a first processor and a second processor disposed opposite to each other with the substrate therebetween in the first direction.

4. The inkjet device of claim 3, wherein
the suction portion includes a first suction portion disposed in the first processor and a second suction portion disposed in the second processor.

5. The inkjet device of claim 4, wherein
each of the first suction portion and the second suction portion extends in a second direction which is orthogonal to the first direction.

6. The inkjet device of claim 5, wherein
each of a width of the first suction portion in the second direction and a width of the second suction portion in the second direction is greater than a width of the substrate in the second direction.

7. The inkjet device of claim 4, wherein
the first suction portion and the second suction portion are disposed between the stage and the inkjet head in a third direction which is perpendicular to a surface of the stage.

8. The inkjet device of claim 7, wherein
the first suction portion and the second suction portion are disposed between the substrate and the inkjet head in the third direction.

9. The inkjet device of claim 7, wherein
the stage includes a plurality of air holes.

10. The inkjet device of claim 4, wherein
the substrate mover further includes a third suction portion.

11. The inkjet device of claim 10, wherein
the third suction portion extends in the first direction.

12. The inkjet device of claim 4, wherein
the substrate mover includes a first substrate mover and a second substrate mover disposed opposite to each other with the substrate therebetween in a second direction which is orthogonal to the first direction.

13. The inkjet device of claim 12, wherein
The first substrate mover includes a fourth suction portion, and
the second substrate mover includes a fifth suction portion.

14. The inkjet device of claim 13, wherein
each of the fourth suction portion and the fifth suction portion extends in the first direction.

15. The inkjet device of claim 1, wherein
the stage includes a plurality of air holes.

16. The inkjet device of claim 1, wherein
the substrate mover further includes a third suction portion.

17. The inkjet device of claim 16, wherein
the third suction portion extends in the first direction.

18. The inkjet device of claim 1, wherein
the substrate mover includes a first substrate mover and a second substrate mover disposed opposite to each other with the substrate therebetween in a second direction which is orthogonal to the first direction.

19. The inkjet device of claim 18, wherein
the first substrate mover includes a fourth suction portion, and
the second substrate mover includes a fifth suction portion.

20. The inkjet device of claim 19, wherein
each of the fourth suction portion and the fifth suction portion extends in the first direction.
